(19) United States
(12) Patent Application Publication
(10) Pub. No.: US 2010/0055865 A1
(43) Pub. Date: Mar. 4, 2010

(54) METHOD OF FABRICATING SEMICONDUCTOR DEVICE

(75) Inventors: Byoung-Hwa YOU, Icheon-si (KR); Seok-Young YOON, Icheon-si (KR)

Correspondence Address: LOWE HAUPTMAN HAM & BERNER, LLP, 1700 DIAGONAL ROAD, SUITE 300, ALEXANDRIA, VA, 22314, US

(73) Assignee: Hynix Semiconductor Inc., Icheon-si (KR)

(21) Appl. No.: 12/344,165

(22) Filed: Dec. 24, 2008

(30) Foreign Application Priority Data
Aug. 29, 2008 (KR) 10-2008-0085098

(51) Int. Cl. H01L 21/76

(52) U.S. Cl. 438/424; 257/E21.54

(57) ABSTRACT

A method of fabricating a semiconductor device includes forming a hardmask pattern over a substrate, forming a line type first photoresist pattern over the hardmask pattern, etching the hardmask pattern using the first photoresist pattern, removing the first photoresist pattern, forming a line type second photoresist pattern that cross the first photoresist pattern over the hardmask pattern, etching the hardmask pattern using the second photoresist pattern as an etch barrier, removing the second photoresist pattern, forming a trench by etching the substrate using the etched hardmask pattern as an etch barrier, and forming a device isolation region by filling the trench with an insulation layer.

### CROSS-REFERENCE TO RELATED APPLICATIONS

The present application claims priority of Korean patent application number 10-2008-0085098, filed on Aug. 29, 2008, which is incorporated herein by reference in its entirety.

### BACKGROUND

One or more embodiments are directed to a semiconductor fabricating technology, and more particularly, to a method of fabricating an active region of a semiconductor device.

The design rules for semiconductor devices have been consistently shrinking. Accordingly, the margin for known masking processes of using photoresist patterns has become insufficient. More recently, hole-type photoresist patterns have been used for defining the active region. However, due to the continuous shrinking of semiconductor devices, the accuracy in hole positioning in the photoresist pattern has reached its limitations. Furthermore, the area of the holes cannot be increased due to the constraint of maintaining uniformly spaced holes.

### SUMMARY

One or more embodiments are directed to a method of fabricating a semiconductor device for overcoming an insufficient margin problem caused by a resolution limitation of a holy-type photoresist pattern that defines an active region.

One or more embodiments are directed to a method of fabricating a semiconductor device, including forming a hardmask layer over a substrate; forming a line type first photoresist pattern over the hardmask pattern; etching the hardmask layer using the first photoresist pattern; removing the first photoresist pattern; forming a line type second photoresist pattern that crosses the first photoresist pattern over the etched hardmask layer; etching the etched hardmask layer using the second photoresist pattern as an etch barrier; removing the second photoresist pattern; forming a trench by etching the substrate using the hardmask pattern as an etch barrier; and forming a device isolation region by filling the trench with an insulation layer.

### BRIEF DESCRIPTION OF THE DRAWINGS

FIGS. 1A and 1B are plan views for describing a method of fabricating a photoresist pattern of an embodiment.

FIG. 2 is a plan view illustrating an active region formed by a photoresist pattern shown in FIGS. 1A and 1B.

FIGS. 3A to 3G are perspective views for describing a semiconductor device fabricating method of an embodiment.

Other objects and advantages of the embodiments can be understood by the following description, and will become apparent in the following disclosure.

### DESCRIPTION OF EMBODIMENTS

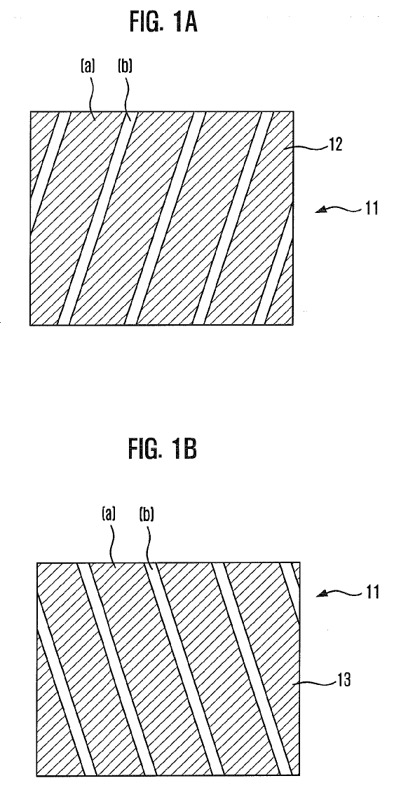

One or more embodiments are directed to a method of forming a device isolation region that defines an active region. When forming the active region from a hole-type photoresist pattern, a space margin becomes insufficient due to limitations on the resolution of the photoresist pattern. In order to overcome this problem, the exposure margin of hole-type photoresist patterns remains consistent by using linear type first and second photoresist patterns. This will be described in detail with reference to FIGS. 1A and 1B.

FIGS. 1A and 1B are plan views for describing a method of fabricating a photoresist pattern of one embodiment.

As shown in FIG. 1A, a first line type photoresist pattern 12 is formed over a substrate 11. The first photoresist pattern 12 is formed having an oblique linear pattern with a line (a)/space (b) formation. Here, the line part of the first photoresist pattern 12 covers an active region, and the space part of the first photoresist pattern 12 defines a device isolation region. The line part has a larger width than the space part.

Unlike in hole-type photoresist patterns, obtaining sufficient exposure margin is possible with a line type a photoresist pattern 12. As shown in FIG. 1B, a line type second photoresist pattern 13 is formed over the substrate 11. The second photoresist pattern 13 is formed having an oblique linear pattern with a line (a)/space (b) formation. Here, the line part of the second photoresist pattern 13 covers an active region, and the space part of the second photoresist pattern 13 defines a device isolation region. The line part has a larger width than that of the space part.

Particularly, the second photoresist pattern 13 is formed with an oblique linear pattern that crosses the oblique linear pattern of the first photoresist pattern 12 shown in FIG. 1A.

Unlike the known hole-type photoresist patterns, obtaining a sufficient exposure margin is possible with the line type first and second photoresist patterns 12 and 13, as described above. Also, the line type first and second photoresist patterns 12 and 13 enable the active region to have a large cell pitch about 1.8 times larger than the active region of the known hole-type photoresist pattern.

The known hole-type photoresist pattern needs to have a wide device isolation region to obtain a sufficient exposure margin. However, despite a reduced gap between the active regions, the line type photoresist patterns 12 and 13 still provide a sufficient exposure margin. Therefore, a high density semiconductor device can be formed.

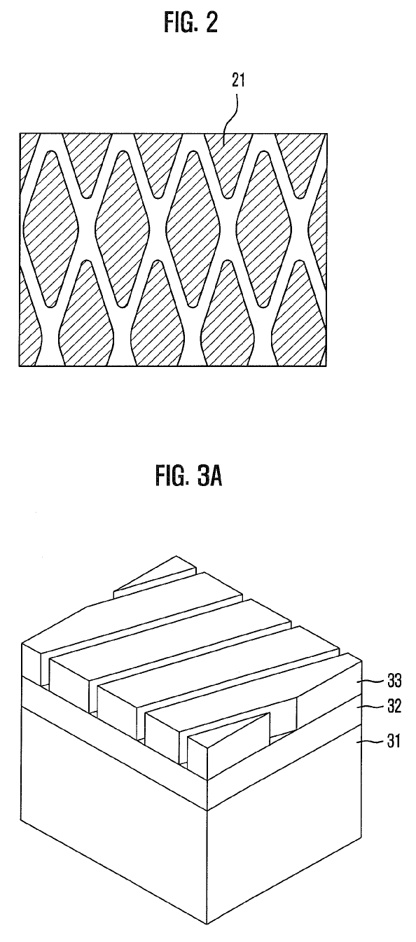

FIG. 2 is a plan view illustrating an active region formed by a photoresist pattern shown in FIGS. 1A and 1B.

As shown in FIG. 2, a hardmask pattern 21 is formed through an etching process using the first and second photoresist patterns displayed in FIGS. 1A and 1B. The hardmask pattern 21 is formed in a diamond shape having horizontal and vertical axes.

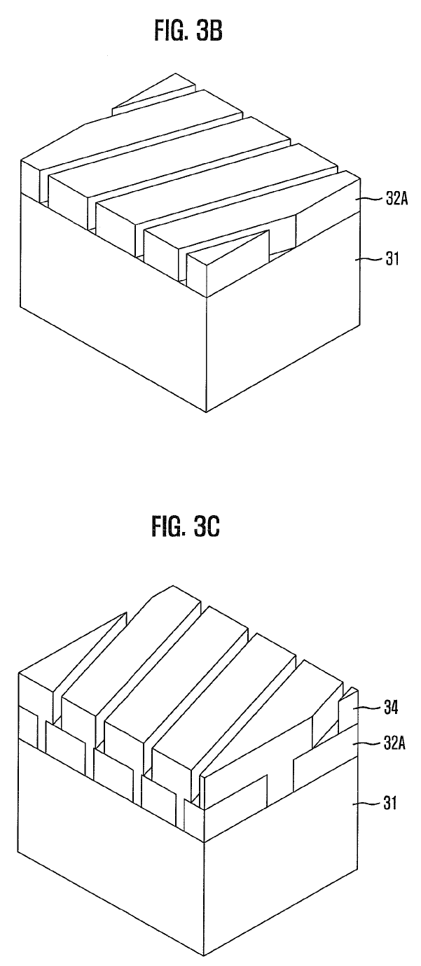

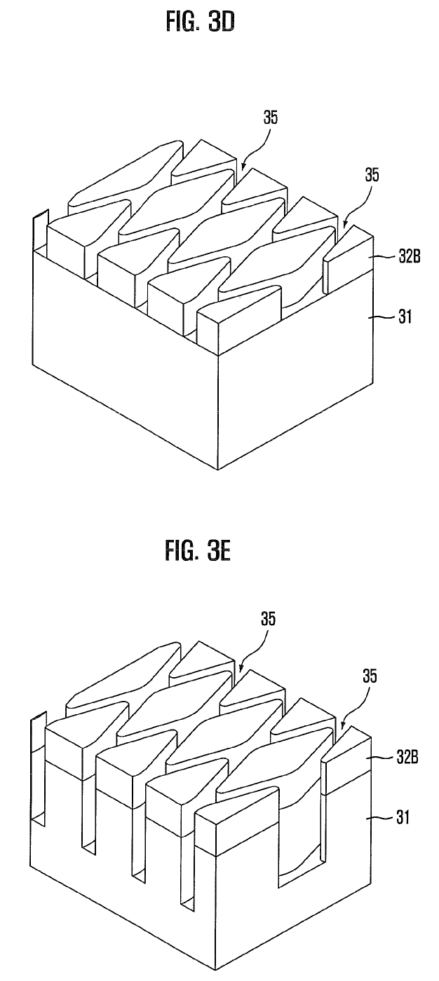

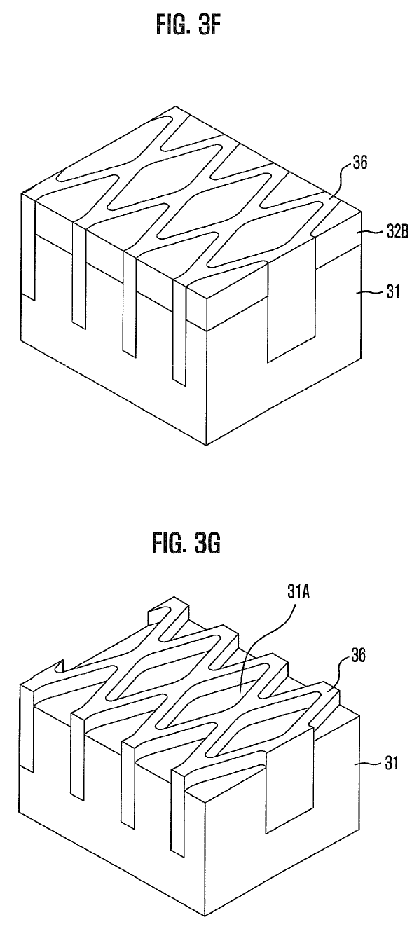

FIGS. 3A and 3B are perspective views for describing a method of fabricating a semiconductor device of an embodiment.

As shown in FIG. 3A, a hardmask layer 32 is formed over a substrate 31. Since the hardmask layer 32 is used as an etch barrier for etching the substrate 31, using a material having a different selectivity from that of the substrate is preferable. The hardmask layer 32 may include a nitride layer.

A line type first photoresist pattern 33 is formed over the hardmask layer 32. The first photoresist pattern 33 has an oblique linear pattern with a line/space form. Here, the line part of the first photoresist pattern 33 covers an active region, and the space part of the first photoresist pattern 33 defines a device isolation region. The line part has a larger width than the space part.

Unlike hole-type photoresist patterns, obtaining sufficient exposure margin with a line type first photoresist pattern is possible.

As shown in FIG. 3B, a hardmask layer 32 is etched using the first photoresist pattern 33. The etched hardmask layer 32A is formed in an oblique line pattern identically to the first photoresist pattern 33. Then, the first photoresist pattern is removed through a dry etching process. An oxygen strip process can be performed as the dry etching process.

As shown in FIG. 3C, a line type second photoresist pattern 34 is formed over the etched hardmask layer 32A. The second photoresist pattern 34 is formed with an oblique linear pattern that crosses the oblique linear pattern of the first photoresist pattern 33.

The oblique linear pattern of the line type second photoresist pattern 34 has a line/space formation. Also, the line part and the space part of the second photoresist pattern 34 are formed with widths identical to those of the first photoresist pattern 33. The lines have a widths larger than that of the spaces.

As shown in FIG. 3D, the etched hardmask layer 32A is etched using the line type second photoresist pattern 34 as an etch barrier. That is, the hardmask pattern 32B is formed having a diamond shape with horizontal and vertical axes by twice etching the hardmask pattern using the line type first and second photoresist patterns 33 and 34 as described above. The hardmask pattern 32B defines an active region and opens a device isolation region.

As shown in FIG. 3E, a trench 35 is formed by etching the substrate 31 using the hardmask pattern 32B as an etch barrier. A portion of the substrate 31 not within the trench 35 and remaining by the hardmask pattern 32B becomes the active region.

As shown in FIG. 3F, a device isolation region 36 is formed by forming an insulation layer in the trench 35 and performing an etch process or a polishing process.

In more detail, an insulation layer is formed filling the trench 35, and an etch process or a polishing process is performed to expose an upper portion of the hardmask pattern 32B, thereby forming a device isolation region 36.

The insulation layer is preferably formed of an oxide layer. The oxide layer is formed from the group consisting of a High Density Plasma (HDP) oxide layer, a Boron Phosphorus Silicate Glass (BPSG) layer, a Phosphorus Silicate Glass (PSG) layer, a Boron Silicate Glass (BSG) layer, a Tetra Ethyle Ortho Silicate (TEOS) layer, a Un-doped Silicate Glass (USG) layer, a Fluorinated Silicate Glass (FSG) layer, a Carbon Doped Oxide (CDO) layer, and an Organo Silicate Glass (OSG) layer, or as a stacking layer of at least two thereof. Also, the oxide layer may be a layer coated through spin coating, such as a Spin On Dielectric (SOD) layer.

As shown in FIG. 3G, the hardmask pattern 32B is removed. The hardmask pattern 32B may be removed through dry etching or wet etching.

During the process of removing the hardmask pattern and a following cleaning process, a predetermined portion of the device isolation region 36 may be lost and a thickness of the device isolation region 36 may be reduced. An active region 31A is defined between device isolation regions 36 by removing the hardmask pattern 32B. When the hardmask pattern 32B is removed, a thickness of the device isolation region 36 may be lost partially.

By twice etching the hardmask pattern using the first and second photoresist patterns formed with crossing oblique linear patterns, forming an active region with a large pitch of about 1.8 times greater than a hole-type active region while obtaining a sufficient exposure margin of a photoresist pattern becomes possible. Prevention of bridging between active regions while obtaining the exposure margin of the photoresist pattern also becomes possible. Thus, the width of the device isolation region can be reduced, allowing for high density semiconductor device formation.

One or more embodiments are directed to a method of fabricating a semiconductor device with an active region having a pitch about 1.8 times larger than a hole-type active region while obtaining an exposure margin of a photoresist pattern by twice etching the hardmask pattern using crossing line type first and second photoresist patterns. Prevention of bridging between active regions while obtaining an exposure margin of the photoresist pattern also becomes possible. Accordingly, the width of a device isolation region can be reduced, allowing for high density semiconductor device formation.

While some embodiments have been described, it will be apparent to those skilled in the art that various changes and modifications may be made.

What is claimed is:

1. A method of fabricating a semiconductor device, comprising:
forming a hardmask layer over a substrate;
forming a line type first photoresist pattern over the hardmask pattern;
etching the hardmask layer using the first photoresist pattern;
removing the first photoresist pattern;
forming a line type second photoresist pattern that crosses the first photoresist pattern over the etched hardmask layer;
etching the etched hardmask layer using the second photoresist pattern as an etch barrier;
removing the second photoresist pattern;
forming a trench by etching the substrate using the hardmask pattern as an etch barrier; and
forming a device isolation region by filling the trench with an insulation layer.

2. The method of claim 1, wherein the first and second photoresist patterns are formed with oblique linear patterns.

3. The method of claim 1, wherein the hardmask layer includes a material having a selectivity different from a selectivity of the substrate.

4. The method of claim 3, wherein the hardmask layer includes a nitride layer.

5. The method of claim 1, wherein the insulation layer includes an oxide layer.
